(19) United States
(12) Patent Application Publication
(10) Pub. No.: US 2024/0211536 A1
(43) Pub. Date: Jun. 27, 2024

(54) EMBEDDED MATRIX-VECTOR MULTIPLICATION EXPLOITING PASSIVE GAIN VIA MOSFET CAPACITOR FOR MACHINE LEARNING APPLICATION

(71) Applicant: UNIVERSITY OF SOUTHERN CALIFORNIA, Los Angeles, CA (US)

(72) Inventors: Shuo-Wei CHEN, Los Angeles, CA (US); Rezwan RASUL, Los Angeles, CA (US)

(73) Assignee: UNIVERSITY OF SOUTHERN CALIFORNIA, Los Angeles, CA (US)

(21) Appl. No.: 18/288,168

(22) PCT Filed: Apr. 25, 2022
(86) PCT No.: PCT/US2022/026190

§ 371 Date: Oct. 24, 2023

Related U.S. Application Data
(60) Provisional application No. 63/179,510, filed on Apr. 25, 2021.

(51) Int. Cl. G06F 17/16; G06N 3/063

(52) U.S. Cl. CPC G06F 17/16; G06N 3/063

(57) ABSTRACT

A compute in-memory architecture comprising multiple neurons is provided. Each neuron includes one or more storage compute cells, each of which includes a logic circuit configured to receive a multi-bit input and a weight. The weight is defined by one or more weight bits. The logic circuit is further configured to output a control voltage corresponding to logic ‘HIGH’ when XNOR operation between an input sign bit and a corresponding weight bit is 1 and a corresponding input magnitude bit is also 1. A first digital-to-analog converter is formed from a first MOSCAP group in electrical communication with the logic circuit. The first MOSCAP group includes a total number of MOSCAPs equal to input magnitude bit resolution times weight bit resolution. Characteristically, each MOSCAP in the first MOSCAP group has a first end that receives the control voltage, and a second end in electrical communication with a first summation line.

### CROSS-REFERENCE TO RELATED APPLICATIONS

This application claims the benefit of U.S. provisional application Ser. No. 63/179,510 filed Apr. 25, 2021, the disclosure of which is hereby incorporated in its entirety by reference herein.

### STATEMENT REGARDING FEDERALLY SPONSORED RESEARCH OR DEVELOPMENT

The invention was made with Government support under Contract No. N66001-14-1-4049 awarded by the Defense Advanced Research Projects Agency (DARPA). The Government has certain rights to the invention.

### TECHNICAL FIELD

In at least one aspect, a compute in-memory architecture with significant passive gain is provided.

### BACKGROUND

In-memory computing (IMC) has emerged as an attractive alternative to the conventional digital implementation of machine learning algorithms since it can achieve high energy efficiency by limiting the data movement between memory and processing unit. In prior IMC works, multi-bit input is encoded into either pulse count [2] or pulse width [4] or an analog voltage [1,3,5] using a DAC which drives the read bit-line (RBL) or read word-line (RWL) port of the bit cell. Such current-domain computation suffers from static power consumed by the DAC and is limited by the linearity of the current sources necessitating calibration [2]. In comparison, charge-domain computation relaxes the linearity, and static power consumption issue; however, prior work has only explored limited parameter precision, i.e. BNN, and is subject to signal attenuation due to charge loss over parasitic elements [6]. Moreover, those prior arts [1-6] lack support of either negative input or negative/zero weights, preventing from implementing a wider range of networks in the IMC hardware.

Accordingly, there is a need for improved methods of implementing compute in-memory architectures.

### SUMMARY

In at least one aspect, the limitations of the prior art are alleviated by a charge-domain IMC with MOS capacitor-based in-memory DAC to support positive/negative/zero operands for Matrix-Vector Multiplication (MVM). To compensate for the signal attenuation, the voltage dependence of MOS capacitor (MOSCAP) is leveraged to provide a passive gain during computation. In support of representing multi-bit computation results, a linear search ADC topology is described utilizing replica computation capacitors to reduce implementation cost and enhance PVT tolerance.

In another aspect, a compute in-memory architecture comprising multiple neurons is provided. Each neuron includes one or more storage compute cells. Each storage compute cell includes a logic circuit configured to receive a multi-bit input and a weight. The weight is defined by one or more weight bits. The logic circuit is further configured to output a control voltage corresponding to logic ‘HIGH’ when XNOR operation between an input sign bit and a corresponding weight bit is 1 and when a corresponding input magnitude bit is also 1. A first digital-to-analog converter is formed from a first MOSCAP group in electrical communication with the logic circuit. The first MOSCAP group includes a total number of MOSCAPs equal to input magnitude bit resolution times weight bit resolution. Characteristically, each MOSCAP in the first MOSCAP group has a first end that receives the control voltage, and a second end in electrical communication with a first summation line.

In another aspect, each storage compute cell further includes a second digital-to-analog converter formed from a second MOSCAP group in electrical communication with the logic circuit. The second MOSCAP group includes a total number of MOSCAPs same as the first MOSCAP group. Each MOSCAP has a first end that receives the control voltage when XOR operation between the input sign bit and the corresponding weight bit is 1, and the corresponding input magnitude bit is also 1. Each MOSCAP in the second MOSCAP group also having a second end in electrical communication with a second summation line.

In still another aspect, the compute in-memory architecture further incudes a plurality of additional digital-to-analog converter units, each additional digital-to-analog converter unit including an associated logic circuit, an associated first MOSCAP group, and an associated second MOSCAP group, wherein the associated first MOSCAP group is in electrical communication with the first summation line and the associated second MOSCAP group is in electrical communication the second summation line.

In still another aspect, a SRAM In-memory computing macro is provided. The SRAM In-memory computing macro includes at one least storage compute cell-containing layer that includes a first predetermined number of storage compute cells and at least analog to digital converter in electrical communication with the first predetermined number of storage compute cells. The SRAM In-memory computing macro also includes input computer memory (e.g., DFF memory) storing a second predetermined number of words in electrical communication with the first predetermined number of storage compute cells such that the first predetermined number is equal to the second predetermined number. The SRAM In-memory computing macro also includes shared control logic in electrical communication with the at one least storage compute cell-containing layer and the input computer memory. The SRAM In-memory computing macro also includes peripheral read and write circuits in electrical communication with the first predetermined number of storage compute cells. Characteristically, each storage compute cell includes a logic circuit configured to receive a multi-bit input and a weight, the weight being defined by one or more weight bits. The logic circuit is further configured to output a control voltage corresponding to logic ‘HIGH’ when XNOR operation between an input sign bit and a corresponding weight bit is 1 and when a corresponding input magnitude bit is also 1. A first digital-to-analog converter formed from a first MOSCAP group in electrical communication with the logic circuit. The first MOSCAP group includes a total number of MOSCAPs equal to input magnitude bit resolution times weight bit resolution. Each MOSCAP in the first MOSCAP group has a first end that receives the control voltage and a second end in electrical communication with a first summation line.

Advantageously, a sub-maximum number of MOSCAPs are typically activated in the compute in-memory architecture such that the voltage dependence of the MOSCAPs provide passive gain during computation.

To validate the compute in-memory architecture, a 16 Kb SRAM-IMC prototype performs MVM operation on 128-elements 5 b signed input vector and 128×64 ternary weight matrix to generate 64 5 b signed outputs in one computation cycle. A fabricated in 65 nm CMOS demonstrates an energy efficiency of 331 TOPS/W with input-output precision of 5-bit and a throughput of 6.4 GOPS.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

For a further understanding of the nature, objects, and advantages of the present disclosure, reference should be had to the following detailed description, read in conjunction with the following drawings, wherein like reference numerals denote like elements and wherein:

FIG. 1A. Schematic of a storage compute cell used in the compute in-memory architecture of the present invention.

FIG. 1B. Schematic of a CDAC used in the storage compute cell of FIG. 1B.

FIGS. 2B-1, 2B-2, and 2B-3. Examples of input weights W and activations X.

FIG. 3A. Implementation of the first MOSCAP group for the input examples of FIGS. 1B-1 and 1B-2.

FIG. 3B. Implementation of the second MOSCAP group for the input examples of FIGS. 1B-1 and 1B-2.

FIG. 4. An architecture of In-Memory Computing with SCC of FIGS. 1A and 1B.

FIG. 5. Passive gained MAV via MOS capacitor array.

FIGS. 6A and 6B. Schematics illustrating a 5-bit linear search ADC for quantizing MAV.

FIG. 7A. Schematic of a compensation resistor to mitigate leakage current, and measurements over temperature/volt variations and chips.

FIG. 7B. Plot of Integral Non-Linearity (LSB) versus ideal MAC value (LSB).

FIG. 7C. Plot of measured output (LSB) versus ideal MAC value (LSB).

FIGS. 8A, 8B, 8C, and 8D. A) classification error, B) measured accuracy using 1K MNIST samples, C) power breakdown and d) energy efficiency at different supply voltages.

FIG. 9. Comparison table with state-of-the-art IMC chips.

### DETAILED DESCRIPTION

Reference will now be made in detail to presently preferred embodiments and methods of the present invention, which constitute the best modes of practicing the invention presently known to the inventors. The Figures are not necessarily to scale. However, it is to be understood that the disclosed embodiments are merely exemplary of the invention that may be embodied in various and alternative forms. Therefore, specific details disclosed herein are not to be interpreted as limiting, but merely as a representative basis for any aspect of the invention and/or as a representative basis for teaching one skilled in the art to variously employ the present invention.

It is also to be understood that this invention is not limited to the specific embodiments and methods described below, as specific components and/or conditions may, of course, vary. Furthermore, the terminology used herein is used only for the purpose of describing particular embodiments of the present invention and is not intended to be limiting in any way.

It must also be noted that, as used in the specification and the appended claims, the singular form “a,” “an,” and “the” comprise plural referents unless the context clearly indicates otherwise. For example, reference to a component in the singular is intended to comprise a plurality of components.

The term “comprising” is synonymous with “including,” “having,” “containing,” or “characterized by.” These terms are inclusive and open-ended and do not exclude additional, unrecited elements or method steps.

The phrase “consisting of” excludes any element, step, or ingredient not specified in the claim. When this phrase appears in a clause of the body of a claim, rather than immediately following the preamble, it limits only the element set forth in that clause; other elements are not excluded from the claim as a whole.

The phrase “consisting essentially of” limits the scope of a claim to the specified materials or steps, plus those that do not materially affect the basic and novel characteristic(s) of the claimed subject matter.

With respect to the terms “comprising,” “consisting of,” and “consisting essentially of,” where one of these three terms is used herein, the presently disclosed and claimed subject matter can include the use of either of the other two terms.

It should also be appreciated that integer ranges explicitly include all intervening integers. For example, the integer range 1-10 explicitly includes 1, 2, 3, 4, 5, 6, 7, 8, 9, and 10. Similarly, the range 1 to 100 includes 1, 2, 3, 4 . . . 97, 98, 99, 100. Similarly, when any range is called for, intervening numbers that are increments of the difference between the upper limit and the lower limit divided by 10 can be taken as alternative upper or lower limits. For example, if the range is 1.1. to 2.1 the following numbers 1.2, 1.3, 1.4, 1.5, 1.6, 1.7, 1.8, 1.9, and 2.0 can be selected as lower or upper limits.

When referring to a numerical quantity, in a refinement, the term “less than” includes a lower non-included limit that is 5 percent of the number indicated after “less than.” A lower non-includes limit means that the numerical quantity being described is greater than the value indicated as a lower non-included limited. For example, “less than 20” includes a lower non-included limit of 1 in a refinement. Therefore, this refinement of “less than 20” includes a range between 1 and 20. In another refinement, the term “less than” includes a lower non-included limit that is, in increasing order of preference, 20 percent, 10 percent, 5 percent, 1 percent, or 0 percent of the number indicated after “less than.”

For any device described herein, linear dimensions and angles can be constructed with plus or minus 50 percent of the values indicated rounded to or truncated to two significant figures of the value provided in the examples. In a refinement, linear dimensions and angles can be constructed with plus or minus 30 percent of the values indicated rounded to or truncated to two significant figures of the value provided in the examples. In another refinement, linear dimensions and angles can be constructed with plus or minus 10 percent of the values indicated rounded to or truncated to two significant figures of the value provided in the examples.

With respect to electrical devices, the term “connected to” means that the electrical components referred to as connected to are in electrical communication. In a refinement, “connected to” means that the electrical components referred to as connected to are directly wired to each other. In another refinement, “connected to” means that the electrical components communicate wirelessly or by a combination of wired and wirelessly connected components. In another refinement, “connected to” means that one or more additional electrical components are interposed between the electrical components referred to as connected to with an electrical signal from an originating component being processed (e.g., filtered, amplified, modulated, rectified, attenuated, summed, subtracted, etc.) before being received to the component connected thereto.

The term “electrical communication” means that an electrical signal is either directly or indirectly sent from an originating electronic device to a receiving electrical device. Indirect electrical communication can involve processing of the electrical signal, including but not limited to, filtering of the signal, amplification of the signal, rectification of the signal, modulation of the signal, attenuation of the signal, adding of the signal with another signal, subtracting the signal from another signal, subtracting another signal from the signal, and the like. Electrical communication can be accomplished with wired components, wirelessly connected components, or a combination thereof.

The term “one or more” means “at least one” and the term “at least one” means “one or more.” The terms “one or more” and “at least one” include “plurality” as a subset.

The term “substantially,” “generally,” or “about” may be used herein to describe disclosed or claimed embodiments. The term “substantially” may modify a value or relative characteristic disclosed or claimed in the present disclosure. In such instances, “substantially” may signify that the value or relative characteristic it modifies is within ±0%, 0.1%, 0.5%, 1%, 2%, 3%, 4%, 5% or 10% of the value or relative characteristic.

The term “electrical signal” refers to the electrical output from an electronic device or the electrical input to an electronic device. The electrical signal is characterized by voltage and/or current. The electrical signal can be stationary with respect to time (e.g., a DC signal) or it can vary with respect to time.

The term “electronic component” refers is any physical entity in an electronic device or system used to affect electron states, electron flow, or the electric fields associated with the electrons. Examples of electronic components include, but are not limited to, capacitors, inductors, resistors, thyristors, diodes, transistors, etc. Electronic components can be passive or active.

The term “electronic device” or “system” refers to a physical entity formed from one or more electronic components to perform a predetermined function on an electrical signal.

It should be appreciated that in any figures for electronic devices, a series of electronic components connected by lines (e.g., wires) indicates that such electronic components are in electrical communication with each other. Moreover, when lines directed connect one electronic component to another, these electronic components can be connected to each other as defined above.

Throughout this application, where publications are referenced, the disclosures of these publications in their entireties are hereby incorporated by reference into this application to more fully describe the state of the art to which this invention pertains.

### Abbreviations

“ADC” means analog-to-digital converter.

“CDAC” means capacitor digital-to-analog converter.

“DAC” means digital-to-analog converter.

“IMC” means In-memory computing.

“LSB” means least significant bit.

“MOM” means metal-oxide-metal.

“MIM” means metal-insulator-metal.

“MSB” means most significant bit.

“MOSCAP” means MOS capacitor.

“MOS” means metal-oxide-semiconductor.

“MVM” means Matrix-Vector Multiplication.

“SCC” means storage compute cells.

“SRAM” means static random-access memory.

“TOPS/W” means tera-operations per second per watt.

The term “neuron” means one/multiple storage compute cells, followed by an ADC.

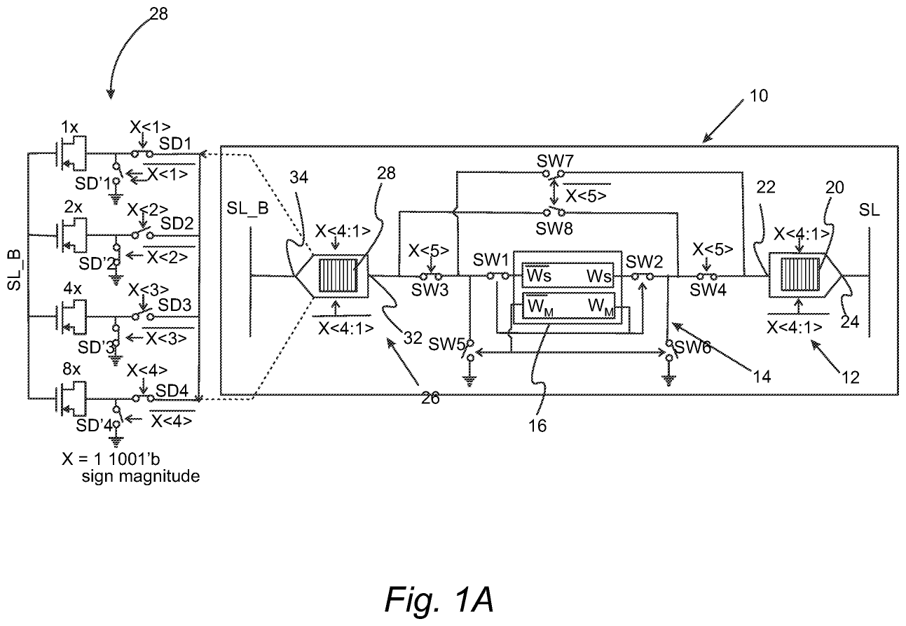

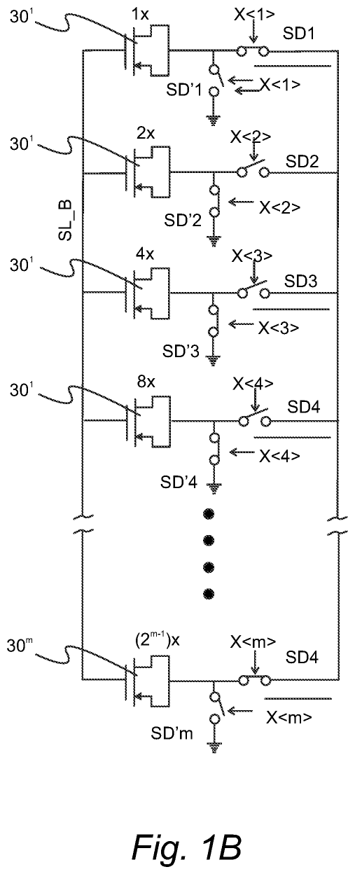

In an embodiment, a compute in-memory architecture including multiple neurons is provided. Each neuron includes one or more storage compute cells. FIG. 1A depicts storage compute cell used in the compute in-memory architecture of the present invention. Storage compute cell 10 includes at least one digital-to-analog converter unit 12 and a logic circuit 14 configured to receive a multi-bit input X and a weight. The weight is defined by one or more weight bits (e.g., W_{S} and W_{M}). The weight bits can be stored in a static or dynamic memory cell. In a refinement, the weight bits are stored in a static memory cell 16. The logic circuit 14 is further configured to output an output a control voltage (e.g., V_{DD} which can be a supply line voltage usually 1 to 5 volts) corresponding to logic ‘HIGH’ when XNOR operation between an input sign bit and a corresponding weight bit is 1 and a corresponding input magnitude bit is also 1. Otherwise, the control signal (e.g., V_{SS} which is typically the lowest voltage in the cell such as ground) can correspond to logic “LOW.” Digital-to-analog converter unit 12 is in electrical communication with the logic circuit 14. Advantageously, digital-to-analog converter unit 12 is formed from a first MOSCAP group 20. Therefore, digital-to-analog converter unit 12 can be referred to as a first CDAC. The first MOSCAP group 20 includes a total number of MOSCAPs equal to input magnitude bit resolution times weight bit resolution. Each MOSCAP in the first MOSCAP group has a first end that receives the control voltage Vdd at input 22 and a second end in electrical communication at input 24 with a first summation line SL. The control voltage can ground or a non-zero voltage.

Still referring to FIG. 1A, storage compute cell 10 further includes a second digital converter 26 (e.g., a second CDAC) formed from a second MOSCAP group 28 in electrical communication with the logic circuit 14. The second MOSCAP group 28 includes a total number of MOSCAPs that is the same (i.e., equal to) as the number of MOSCAPs in the first MOSCAP group. Characteristically, each MOSCAP has a first end 32 that receives the control voltage when XOR operation between the input sign bit and the corresponding weight bit is 1, and the corresponding input magnitude bit is also 1. Each MOSCAP in the second MOSCAP group also has a second end 34 in electrical communication with a second summation line SL_B.

FIG. 1B provides a schematic of a MOSCAP group that can be used for MOSCAP groups 20 and 28. In general, MOSCAP groups 20 and 28 include m MOSCAPs 30 where m is an integer equal to the number of MOSCAPs with each MOSCAP corresponding to a single bit (e.g., a magnitude bit).

Referring to FIGS. 1A and 1B, storage compute cell 10 also includes switched SW1-SW8. Similarly, first MOSCAP group 20 and second MOSCAP group 28 include switches SD′1-SD′4. In the general case, the first MOSCAP group 20 and the second MOSCAP group 28 include switches SD1-SDm and switches SD′1-SD′m. All the switches in combination are used to provide a switching scheme as described below for FIGS. 2B-1, 2B-2, and 2B-3.

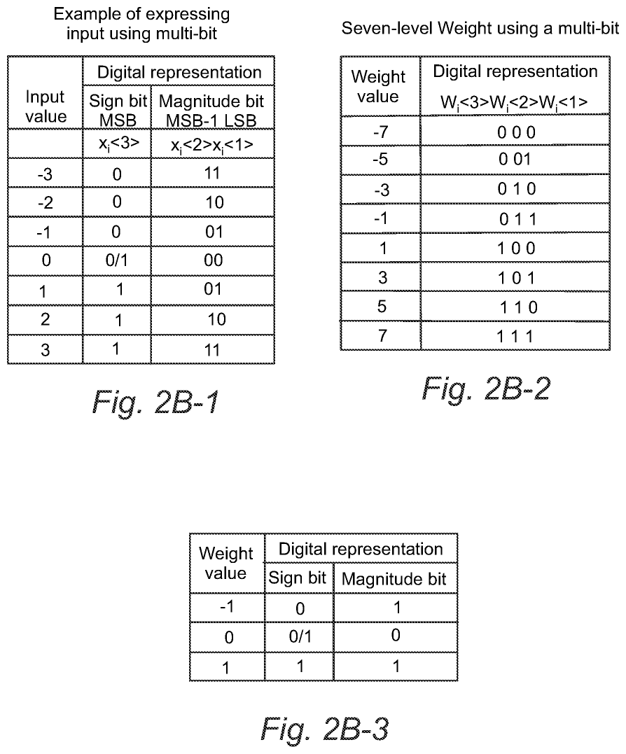

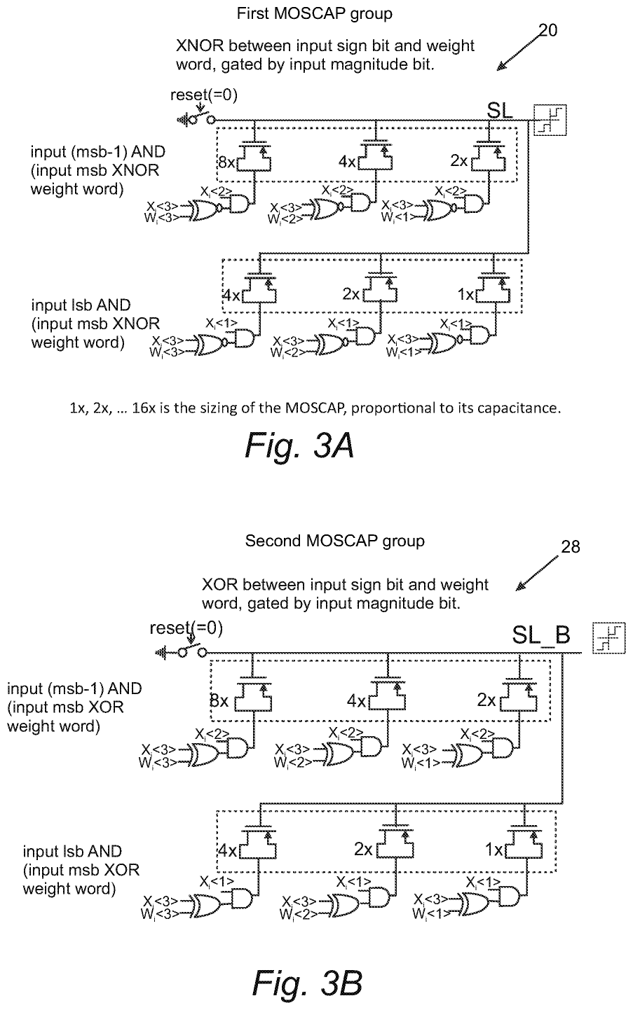

FIGS. 2B-1, 2B-2, and 2B-3 provide examples for the multi-bit input X and a weight W received by logic circuit 14. FIG. 2B-1 provides an example of a 3-bit input X, with the most significant bit being a sign bit. In the example depicted, 7 numbers are represented since for an input value of 0 the sign bit can be 0 or 1 when the magnitude bits are <00>. In other words, ‘0’ is expressed by two different bit representations. It should be noted, that for a 3-bit input, 8 numbers could be represented. FIG. 2B-2 provides an example of a 3-bit weight mapping to weight from −7 to 7. It should be noted that ‘0’ is not represented. FIG. 2B-3 provides an example of a 2-bit weight mapping to weights of −1 to 1. In this tri-level construction ‘0’ is also represented by two different representations.

FIGS. 3A and 3B provide schematics of a design implementation of the compute in-memory architecture using the inputs of FIGS. 1B-1 and 1B-2. As depicted in 1D, the relative capacitances of the MOSCAPs can be sized to differentiate the different combinations of weights W and multi-bit input X. Therefore, 1×, 2×, . . . 16× are the relative sizing of the MOSCAPs, which are proportional to the capacitance.

In a variation, the compute in-memory architecture includes a plurality of additional storage compute cells. Each additional storage compute cell includes an associated logic circuit, an associated first MOSCAP group, and an associated second MOSCAP group. Characteristically, the associated first MOSCAP group is in electrical communication with the first summation line and the associated second MOSCAP group is in electrical communication the second summation line SL_B.

In a variation, the voltage difference between the first summation line and the second summation line is proportional to the multiplication result between an input vector and a weight vector, the voltage difference being an analog voltage output.

In a variation, a plurality of neurons are arranged to represent a complete or a partial layer of a neural network.

In another variation, a sub-maximum number of MOSCAPs of a DAC are activated such that the voltage dependence of the MOSCAPs provide a passive gain during computation.

In a variation, each digital-to-analog converter unit is first biased at the minimum capacitance (Cmin), during a reset phase (Reset=1) because voltage difference across MOSCAP terminals is zero. Moreover, during a computation phase, some MOSCAPs are activated by connecting to VDD when the corresponding control voltage is HIGH, thereby causing a large voltage difference across those capacitors thereby increasing their capacitance to an inversion-mode value (Cmax). The larger capacitance pulls up the voltage of first summation line even higher.

In another variation, MOSCAPs in the first MOSCAP group and the second MOSCAP group are sized to achieve an appropriate capacitance ratio corresponding to different bit positions of the multi-bit input and weight.

In another variation, the compute in-memory architecture is configured to support positive/negative/zero value of inputs and weights for Matrix-Vector Multiplication (MVM) operation.

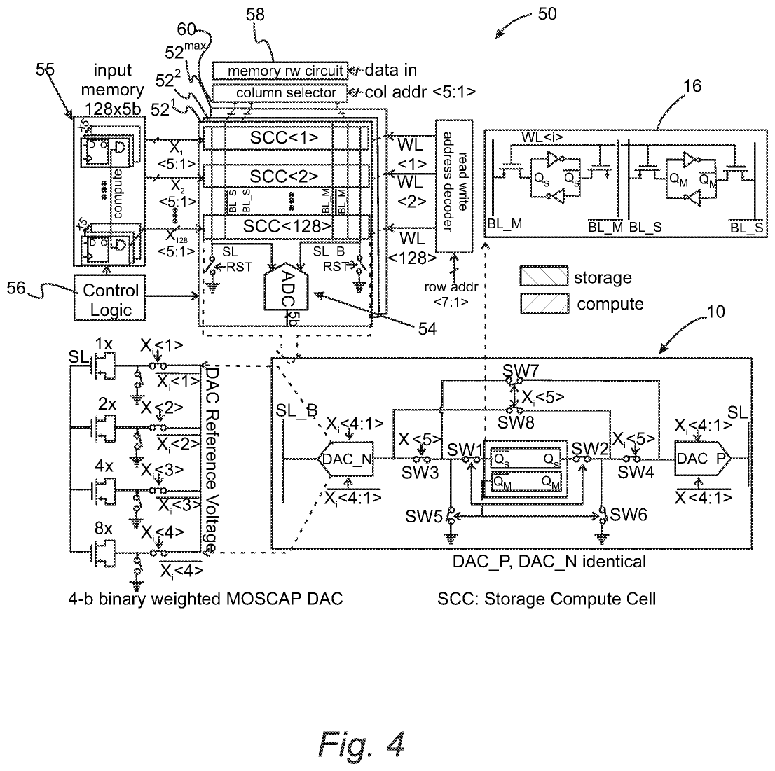

FIG. 4 shows the compute in-memory architecture of an SRAM IMC macro. The SRAM In-memory computing macro 50 includes at one least storage compute cell-containing layer 52¹ and typically plurality storage compute cell-containing layer 52ⁱ where i is an integer label (i.e., e.g., 1 to the total number of layers−iₘₐₓ). Each storage compute cell-containing layer 52ⁱ that includes a first predetermined number of storage compute cells 10 as described above and at least one analog to digital converter 54 in electrical communication with the first predetermined number of storage compute cells. Each storage compute cells 10 includes static memory cell(s) 16 as described above. Typically, the first predetermined number of storage compute cells is the same for each storage compute cell-containing layer 52ⁱ. The SRAM In-memory computing macro 50 also includes input computer memory 55 (e.g., DFF memory) storing a second predetermined number of words. Typically, the first predetermined number of storage compute cells 10 in each storage compute cell-containing layer 52 is the same as the second predetermined number of words.

The input computer memory is in electrical communication with the first predetermined number of storage compute cells 10 such that the first predetermined number is equal to the second predetermined number. The SRAM In-memory computing macro 50 also includes shared control logic 56 in electrical communication with the at one least storage compute cell-containing layer and the input computer memory. The SRAM In-memory computing macro 50 also includes peripheral read and write circuits 58 and column selector circuit 60 in electrical communication with the first predetermined number of storage compute cells.

BLM_S and BL_M bit lines are used for reading from and writing data to the storage compute cells 10, and in particular, for reading from and writing data to static memory cell(s) 16. Claim selection is attached by activating a BLM_S line and its complement, a BL_M line and its complement, and a summation line and its complement. Typically, the storage compute cell-containing layer 52ⁱ are activated one at a time, and in particular, sequentially in this manner.

Still referring to FIG. 4, each storage compute cell has the architecture describe above with respect to FIGS. 1-3. In the specific depiction of FIG. 4, SRAM IMC macro 50 includes 128×64 storage compute cells (SCC) 52, 64 ADCs 54, 128×5 b input DFF memory 54, shared control logic 56, and peripheral read and write circuits. Each SCC performs an elementwise multiply-and-average (MAV) between a ternary weight stored in sign bit-cell (Qs), and magnitude bit-cell (Q_{M}) format and an input Xi<5:1>. A switching scheme can incorporate negative, zero, and positive operands using minimum-sized switches (S1˜S8). Examples of switching scheme are depicted in FIGS. 2B-1, 2B-2, and 2B-3 and the related description set forth above. For zero operand, either QM is 0 or the input magnitude bits Xi<4:1> is 4′h0, therefore, no capacitor in the MOSCAP DAC is switched during computation. For positive and negative operand, the bitwise product between QS and Xi<4:1> is accumulated in either positive (DAC_P) binary MOSCAP DAC or negative (DAC_N) binary MOSCAP DAC when the input and weight are of equal or opposite sign, respectively. The MOSCAP DAC outputs (SL and SL_B) of 128 SCCs in the same column are physically connected in order to induce differential voltage (VSL−VSL_B) proportional to the MAV between 128 elements input and weight vectors.

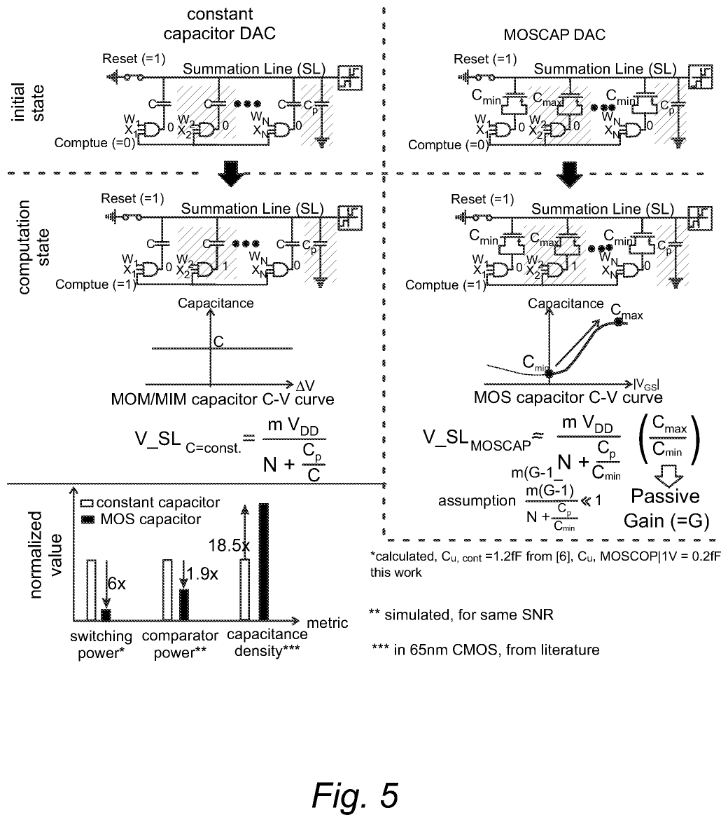

Advantageously, the compute in-memory architecture utilizes a MOSCAP DAC and exploits its voltage-dependent capacitance property for achieving a passive gain. FIG. 5 illustrates the simplified operation for a single-bit weight and input case. For a traditional CDAC using MOM or MIM capacitor, the output during the computation phase (Compute=1) is given by m/N*VDD where Σᵢ₌₁^{N} WᵢXᵢ=m. In comparison, the MOSCAP DAC is first biased at the minimum capacitance, i.e. depletion-mode value (Cmin), during reset phase (Reset=1) because the voltage difference across MOSCAP terminals is zero. Next, during the computation phase, some MOSCAPs are connected to VDD when the corresponding bitwise product is logic HIGH. It causes a large voltage difference across those capacitors, increasing their capacitance to the inversion-mode value (Cmax). This larger capacitance (i.e. lower impedance) pulls up the voltage of SL even higher, i.e. the DAC output is effectively boosted by a passive gain determined by the variable capacitance ratio (G=Cmax/Cmin>1). The enlarged voltage swing helps relax the noise and precision requirement of the following quantizer design. Another advantage of using MOSCAP is its higher capacitance density over the passive capacitor, e.g. MOM capacitor. Moreover, one can design a small unit capacitance with MOSCAP, which further reduces the switching energy dissipation during computation. Note that, the voltage-dependent capacitance can introduce distortion to MAV output, especially when the MAV density (m/N) is high. Fortunately, the density is typically low for representative networks, exercising the linear part of MAV transfer function. To validate, it was confirmed that the measured accuracy of MNIST dataset recognition using LeNet-5 network matches closely (<1%) with software accuracy using ideal MAV. Lastly, the parasitic capacitance at the SL and SL_B nodes further suppresses the nonlinearity effect.

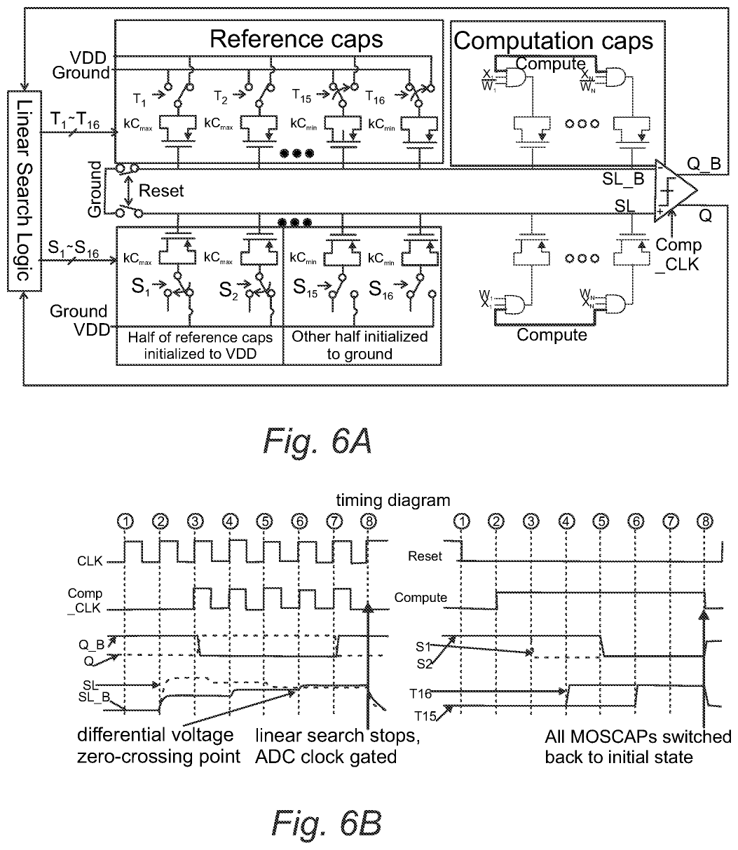

In a variation, the compute in-memory architecture further includes a linear search ADC to quantize analog voltage output between the first summation line and the second summation line. FIG. 6 schematically depicts the linear search ADC to quantize MAV output. The probability distribution function of the MAV output motivates us to perform linear search from the LSB. The ADC utilizes reference replica MOSCAPs attached to the SL and SL_B nodes (FIG. 6), half of which are initialized to VDD and the other half to Ground. During the linear search process, a unit capacitor at either SL or SL_B is toggled to the other supply voltage, depending on the comparator's decision. The search stops when the differential voltage between the nodes crosses zero. The initialization and switching scheme enables the nodes to approach each other alternately instead of keeping either node fixed [1, 3] and hence mitigates the impact of load imbalance between the nodes. The embedded ADC scheme eliminates the need for extra sampling circuitry since the charge is redistributed between reference and computation MOSCAPs. Moreover, better conversion accuracy is achieved due to high relative matching between the same type of capacitors used for computation and reference voltage generation.

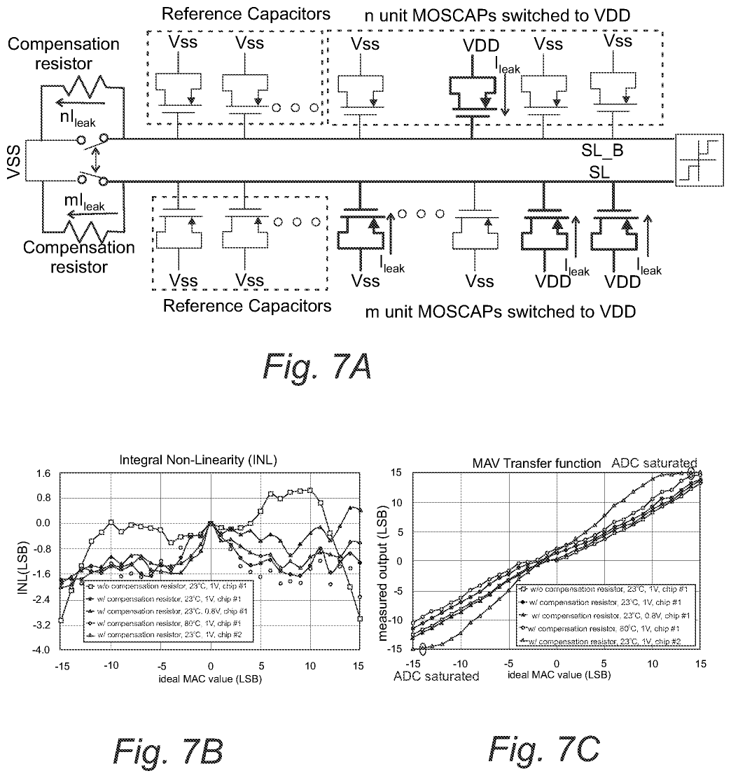

One design consideration for using MOSCAP is the gate leakage current, which may corrupt the preserved charge stored on MOSCAP DAC. Since the various number of MOSCAPs are switched throughout the computation and quantization phase, the charge leakage on SL and SL_B nodes would cause voltage drifting, and hence distort the MAV result. To mitigate the leakage current, we terminate SL and SL_B with a compensation resistor for providing current in the opposite direction to mitigate the leakage current, as shown in FIG. 7. As result of this scheme, the MAV transfer function could avoid early clipping caused by the leakage current. The INL is also reduced to −2.3/+0.4 LSB from its uncompensated value of −3/+1 LSB. The MAV transfer function after compensation varies within 35% across different supply voltages, temperatures, and chips.

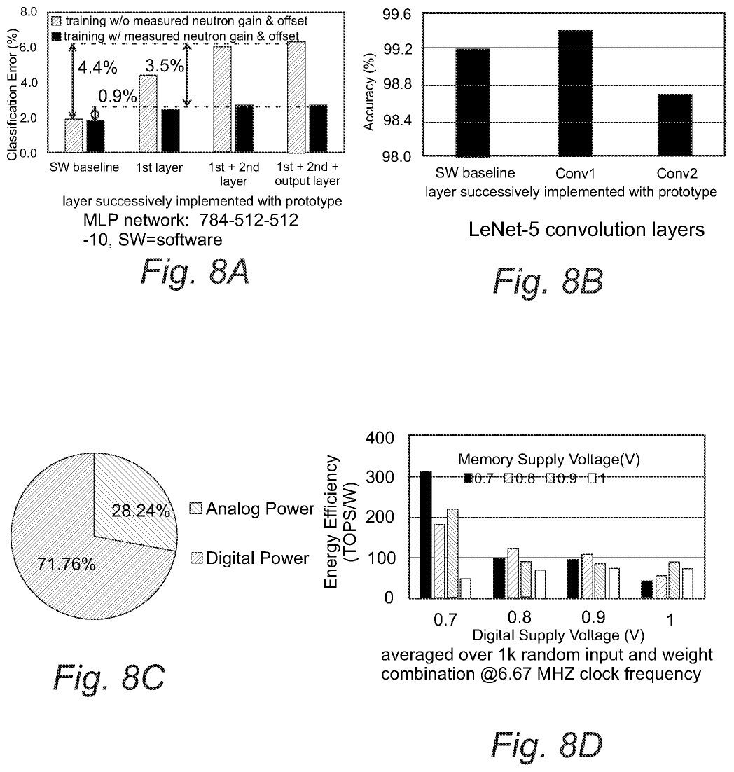

FIG. 8 presents the measurement data using a 16 Kb SRAM-IMC macro test-chip fabricated in 65 nm CMOS. To mitigate circuit non-idealities, we have incorporated in-situ training, i.e. apply the measured MAV transfer function into the software training process, reducing classification error by 3.5% for an MLP network classifying 1 k images from MNIST test-set. The accuracy achieved is 98.7% when using the prototype to perform the 2 convolutional layers of LeNet-5 network. The prototype consumes 49.4 pJ energy when all 64 neurons output a maximum code of +15 at 0.7V supply voltage, resulting in an energy efficiency of 331TOPS/W, the highest reported among SOA IMC works with input-output resolution >4 b. The energy consumption breakdown shows that the digital logic dominates, suggesting an even better energy efficiency can be achieved in more advanced technology nodes.

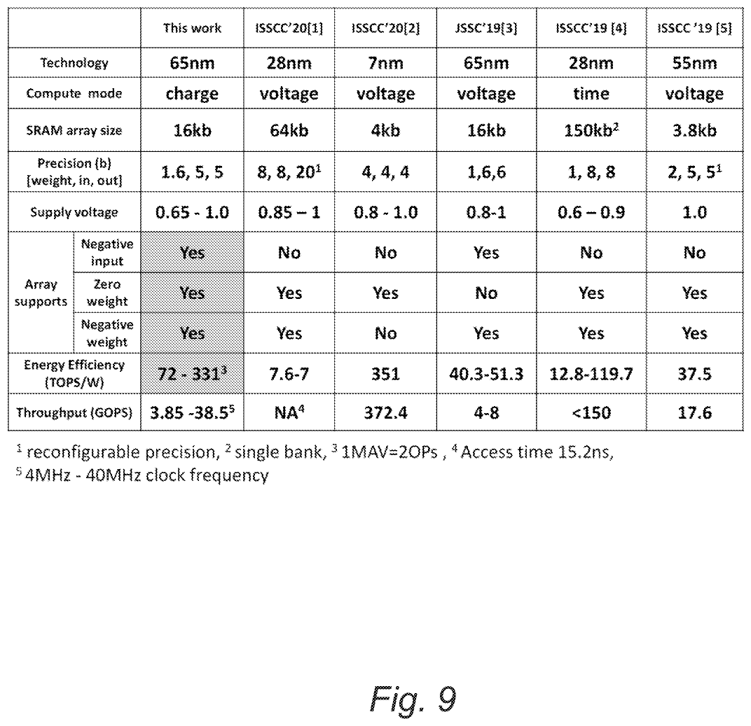

FIG. 9 shows the comparison with other SOA IMC works. For this table, it is clear that the compute in-memory architecture described herein is the only technology allowing positive/negative/zero value of inputs and weights.

Additional details of the SOC described herein are provided in R. A. Rasul and M. S.-W. Chen, “A 128×128 SRAM Macro with Embedded Matrix-Vector Multiplication Exploiting Passive Gain via MOS Capacitor for Machine Learning Application,” 2021 IEEE Custom Integrated Circuits Conference (CICC), 2021, pp. 1-2, doi: 10.1109/CICC51472.2021.9431485 (25-30 Apr. 2021); the entire disclosure of which is hereby incorporated by reference in its entirety.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

What is claimed is:

1. A compute in-memory architecture comprising multiple neurons, each neuron including one or more storage compute cells, each storage compute cell comprising:
a logic circuit configured to receive a multi-bit input and a weight, the weight being defined by one or more weight bits, the logic circuit further configured to output a control voltage corresponding to logic ‘HIGH’ when XNOR operation between an input sign bit and a corresponding weight bit is 1 and when a corresponding input magnitude bit is also 1; and
a first digital-to-analog converter formed from a first MOSCAP group in electrical communication with the logic circuit, the first MOSCAP group including a total number of MOSCAPs equal to input magnitude bit resolution times weight bit resolution, wherein each MOSCAP in the first MOSCAP group has a first end that receives the control voltage, and a second end in electrical communication with a first summation line.

2. The compute in-memory architecture of claim 1 wherein each storage compute cell further includes a second digital-to-analog converter formed from a second MOSCAP group in electrical communication with the logic circuit, the second MOSCAP group including a total number of MOSCAPs same as the first MOSCAP group, where each MOSCAP has a first end that receives the control voltage when XOR operation between the input sign bit and the corresponding weight bit is 1, and the corresponding input magnitude bit is also 1; each MOSCAP in the second MOSCAP group also having a second end in electrical communication with a second summation line.

3. The compute in-memory architecture of claim 2 wherein the control voltage is ground or a non-zero voltage.

4. The compute in-memory architecture of claim 2 wherein the weight bits are stored in a static or dynamic memory cell.

5. The compute in-memory architecture of claim 2 further comprising a plurality of additional storage compute cells, each additional storage compute cell including an associated logic circuit, an associated first MOSCAP group, and an associated second MOSCAP group, wherein the associated first MOSCAP group is in electrical communication with the first summation line and the associated second MOSCAP group is in electrical communication the second summation line.

6. The compute in-memory architecture of claim 2 wherein the voltage difference between the first summation line and the second summation line is proportional to the multiplication result between an input vector and a weight vector, the voltage difference being an analog voltage output.

7. The compute in-memory architecture of claim 5 further comprising a linear search ADC to quantize analog voltage output between the first summation line and the second summation line.

8. The compute in-memory architecture of claim 7 wherein a plurality of neurons are arranged to represent a complete or a partial layer of a neural network.

9. The compute in-memory architecture of claim 7 wherein a sub-maximum number of MOSCAPs of a digital-to-analog converter are activated such that the voltage dependence of the MOSCAPs provide a passive gain during computation.

10. The compute in-memory architecture of claim 7 wherein:
each digital-to-analog converter unit is first biased at the minimum capacitance (Cmin), during a reset phase (Reset=1) because voltage difference across MOSCAP terminals is zero; and
during a computation phase, some MOSCAPs are activated by connecting to VDD when the corresponding control voltage is HIGH, thereby causing a large voltage difference across those capacitors, increasing their capacitance to an inversion-mode value (Cmax), the larger capacitance pulls up the voltage of first summation line even higher.

11. The compute in-memory architecture of claim 10 wherein MOSCAPs in the first MOSCAP group and the second MOSCAP group are sized to achieve an appropriate capacitance ratio corresponding to different bit positions of the multi-bit input and weight.

12. The compute in-memory architecture of claim 11 configured to support positive/negative/zero value of inputs and weights for Matrix-Vector Multiplication (MVM) operation.

13. A SRAM In-memory computing macro comprising:
at one least storage compute cell-containing layer including:
a first predetermined number of storage compute cells;
and at least analog to digital converter in electrical communication with the first predetermined number of storage compute cells;
input computer memory storing a second predetermined number of words, input computer memory in electrical communication with the first predetermined number of storage compute cells, the first predetermined number being equal to the second predetermined number;
shared control logic in electrical communication with the at one least storage compute cell-containing layer and the input computer memory; and
peripheral read and write circuits in electrical communication with the first predetermined number of storage compute cells, wherein each storage compute cell includes:
a logic circuit configured to receive a multi-bit input and a weight, the weight being defined by one or more weight bits, the logic circuit further configured to output a control voltage corresponding to logic ‘HIGH’ when XNOR operation between an input sign bit and a corresponding weight bit is 1 and when a corresponding input magnitude bit is also 1; and
a first digital-to-analog converter formed from a first MOSCAP group in electrical communication with the logic circuit, the first MOSCAP group including a total number of MOSCAPs equal to input magnitude bit resolution times weight bit resolution, wherein each MOSCAP in the first MOSCAP group has a first end that receives the control voltage, and a second end in electrical communication with a first summation line.

14. The SRAM In-memory computing macro of claim 13 configured to perform an elementwise multiply-and-average between a weight stored in sign bit-cell and a magnitude bit-cell cell and an input.

15. The SRAM In-memory computing macro of claim 13, wherein each storage compute cell includes a plurality of switches configured to implement a switching scheme.

16. The SRAM In-memory computing macro of claim 15 wherein the switching scheme incorporates negative, zero, and positive operands.

17. The SRAM In-memory computing macro of claim 15 wherein the at one least storage compute cell-containing layer includes a plurality of storage compute cell-containing layers.

18. The SRAM In-memory computing macro of claim 13, wherein each storage compute cell further includes a second digital-to-analog converter formed from a second MOSCAP group in electrical communication with the logic circuit, the second MOSCAP group including a total number of MOSCAPs same as the first MOSCAP group, where each MOSCAP has a first end that receives the control voltage when XOR operation between the input sign bit and the corresponding weight bit is 1, and the corresponding input magnitude bit is also 1; each MOSCAP in the second MOSCAP group also having a second end in electrical communication with a second summation line.

19. The SRAM In-memory computing macro of claim 18, wherein a voltage difference between the first summation line and the second summation line is proportional to a multiplication result between an input vector and a weight vector, the voltage difference being an analog voltage output.

20. The compute in-memory architecture of claim 9 wherein:
each digital-to-analog converter unit is first biased at a minimum capacitance (Cmin), during a reset phase (Reset=1) because voltage difference across MOSCAP terminals is zero; and
during a computation phase, some MOSCAPs are activated by connecting to a voltage VDD when the corresponding control voltage is HIGH, thereby causing a large voltage difference across those capacitors, increasing their capacitance to an inversion-mode value (Cmax), the larger capacitance pulls up the voltage of first summation line even higher.
